(19) United States
(12) Patent Application Publication
(10) Pub. No.: US 2009/0035929 A1
(43) Pub. Date: Feb. 5, 2009

(54) Method of manufacturing semiconductor device

(75) Inventors: Takeshi Yuzawa, Chino-shi (JP); Hideki Yuzawa, Iida-shi (JP); Michiyoshi Takano, Okaya-shi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 11/905,584

(22) Filed: Oct. 2, 2007

Related U.S. Application Data
(63) Continuation of application No. 11/142,439, filed on Jun. 2, 2005.

(30) Foreign Application Priority Data
Jun. 4, 2004 (JP) 2004-167195

(51) Int. Cl. H01L 21/768

(52) U.S. Cl. 438/613; 257/E21.589

(57) ABSTRACT

A method of manufacturing a semiconductor device includes: (a) forming an insulating layer having a contact hole on a semiconductor section in which an element is formed; (b) forming an electrode pad on the insulating layer so that a depression or a protrusion remains at a position at which the electrode pad overlaps the contact section; (c) forming a passivation film to have an opening on a first section of the electrode pad and to be positioned on a second section of the electrode pad; (d) forming a barrier layer on the electrode pad; and (e) forming a bump to be larger than the opening in the passivation film and to be partially positioned on the passivation film. The contact section is connected with the second section at a position within a range in which the contact section overlaps the bump while avoiding the first section of the electrode pad.

This is a Continuation of application Ser. No. 11/142,439 filed Jun. 2, 2005, which claims the benefit of Japanese Patent Application No. 2004-167195, filed on Jun. 4, 2004. The disclosures of the prior applications are hereby incorporated by reference herein in their entirety.

### BACKGROUND OF THE INVENTION

The present invention relates to a method of manufacturing a semiconductor device.

In order to reduce the planar area of a semiconductor chip, it is known that a bump as an external electrode is caused to overlap a formation region of elements (transistor) (see Japanese Patent Application Laid-open No. 9-283525). An interconnect layer is formed on the formation region of the elements, an insulating layer having an opening is formed on the interconnect layer, a contact section is formed in the opening in the insulating layer, and an electrode pad connected with the contact section is then formed.

In the case of integrally depositing the contact section and the electrode pad by sputtering, a tapered surface is formed at the open end of the insulating layer to allow a conductive material to be easily deposited. A depression is formed on the surface of the electrode pad to follow the tapered surface at a position at which the electrode pad overlaps the contact section. The depression may be removed by a planarization process by polishing and grinding the electrode pad in the subsequent step. However, it is desirable to omit the planarization process since the number of processes and cost are increased.

If the depression is formed on a part of the electrode pad, a barrier layer formed on the electrode pad for preventing diffusion between the electrode pad and the bump may exhibit inferior barrier performance at a position corresponding to the depression. As a result, electrical connection reliability of the electrode pad near the contact section may deteriorate.

In the case where the contact section and the electrode pad are formed by different processes, such as in the case where the contact section is deposited by using a CVD method and the electrode pad is deposited by sputtering, a depression (due to depression on the contact section) or a protrusion (due to protrusion on the contact section) may also be formed on the electrode pad. In this case, the barrier layer may also exhibit inferior barrier performance at a position corresponding to the depression or protrusion, whereby electrical connection reliability may deteriorate.

The thickness of the barrier layer in the case where the depression or protrusion is not formed is usually about 2000 to 5000 angstroms. If the thickness of the barrier layer is increased in order to prevent deterioration of the barrier performance, cost is increased. Therefore, it is desirable to increase the barrier performance without increasing the thickness of the barrier layer.

### SUMMARY

One aspect of the present invention relates to a method of manufacturing a semiconductor device, the method comprising:

(a) forming an insulating layer having a contact hole for a contact section on a semiconductor section in which an element is formed;

(b) forming an electrode pad on the insulating layer so that a depression or a protrusion remains at a position at which the electrode pad overlaps the contact section;

(c) forming a passivation film to have an opening on a first section of the electrode pad and to be positioned on a second section of the electrode pad;

(d) forming a barrier layer on the electrode pad; and

(e) forming a bump to be larger than the opening in the passivation film and to be partially positioned on the passivation film,

wherein the contact section is connected with the second section at a position within a range in which the contact section overlaps the bump while avoiding the first section of the electrode pad.

### BRIEF DESCRIPTION OF THE SEVERAL VIEWS OF THE DRAWING

FIG. 1 is a plan view of a semiconductor device manufactured by using a method according to an embodiment of the invention.

FIG. 2 is a partially enlarged view along the line II-II shown in FIG. 1.

FIGS. 3A to 3C show a method of manufacturing a semiconductor device according to this embodiment.

FIGS. 4A to 4C show a modification of a method of manufacturing a semiconductor device according to this embodiment.

FIGS. 5A to 5C show the modification of a method of manufacturing a semiconductor device according to this embodiment.

### DETAILED DESCRIPTION OF THIS EMBODIMENT

The invention may improve electrical connection reliability without performing the planarization process or increasing the thickness of the barrier layer.

A method of manufacturing a semiconductor device according to one embodiment of the present invention comprises:

(a) forming an insulating layer having a contact hole for a contact section on a semiconductor section in which an element is formed;

(b) forming an electrode pad on the insulating layer so that a depression or a protrusion remains at a position at which the electrode pad overlaps the contact section;

(c) forming a passivation film to have an opening on a first section of the electrode pad and to be positioned on a second section of the electrode pad;

(d) forming a barrier layer on the electrode pad; and

(e) forming a bump to be larger than the opening in the passivation film and to be partially positioned on the passivation film,

wherein the contact section is connected with the second section at a position within a range in which the contact section overlaps the bump while avoiding the first section of the electrode pad.

According to this embodiment, the contact section is connected with the second section of the electrode pad. This enables the depression or protrusion on the electrode pad to be formed in the second section. Since the passivation film is positioned on the second section of the electrode pad, deterioration of the barrier performance of the barrier layer due to the depression or protrusion can be prevented. Therefore, electrical connection reliability can be improved while using the process in which the planarization process is omitted and which causes the depression or protrusion to remain on the electrode pad.

(2) With this method of manufacturing a semiconductor device,

the step (b) may include forming the electrode pad and the contact section at the same time.

(3) With this method of manufacturing a semiconductor device,

the step (a) may include forming a tapered surface extending in an open direction at an open end of the contact hole in the insulating layer, and

the step (b) may include forming the depression on the electrode pad to follow the tapered surface.

(4) With this method of manufacturing a semiconductor device,

the step (b) may include forming the electrode pad after forming the contact section.

(5) With this method of manufacturing a semiconductor device, the step (b) may include:

(b₁) forming the contact section so that a depression is formed in the contact hole; and

(b₂) forming the depression on the electrode pad to follow the depression on the contact section.

(6) With this method of manufacturing a semiconductor device, the step (b) may include:

(b₁) forming the contact section so that a protrusion is formed on the contact hole; and

(b₂) forming the protrusion on the electrode pad to follow the protrusion on the contact section.

(7) With this method of manufacturing a semiconductor device,

the bump may overlap a formation region of the element in the semiconductor section.

(8) With this method of manufacturing a semiconductor device,

the step (d) may include forming the barrier layer so that a part of the barrier layer is positioned on the passivation film, and

the step (e) may include causing the passivation film and the barrier layer to lie between the second section of the electrode pad and the bump.

According to this feature, the barrier layer lies between the second section and the bump in addition to the passivation film. Therefore, diffusion between the electrode pad and the bump can be more effectively prevented.

(9) This method of manufacturing a semiconductor device may comprise:

forming a plurality of the contact sections,

the contact sections may be symmetrically arranged around a center axis of the bump.

This enables the mechanical stress applied through the bump due to the packaging process or the like to be evenly dispersed. Therefore, occurrence of damage to the contact section or the electrode pad due to stress concentration can be prevented.

The embodiments of the invention are described below with reference to the drawings.

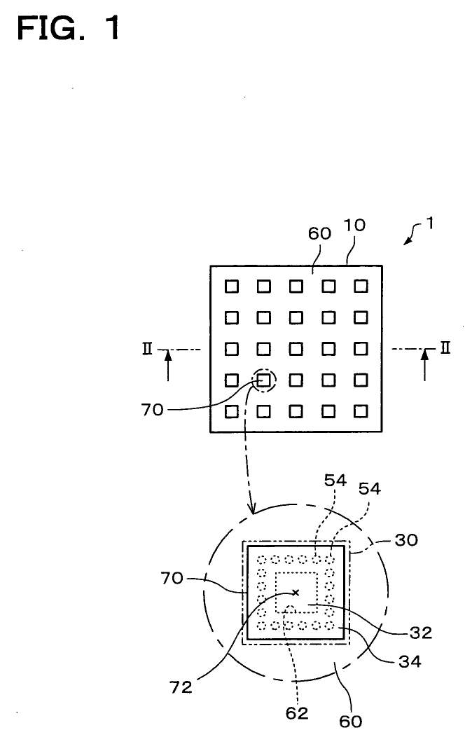

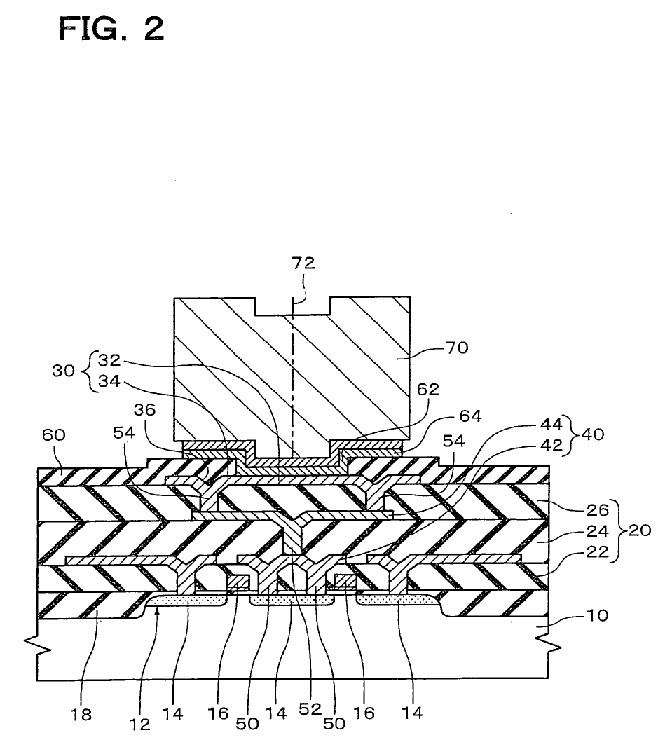

FIG. 1 is a plan view of a semiconductor device manufactured by using a method according to an embodiment of the invention, and FIG. 2 is a partially enlarged view along the line II-II shown in FIG. 1.

The semiconductor device manufactured by using the method according to this embodiment may be a semiconductor chip (bare chip) (see FIG. 1), or may be a semiconductor wafer before being cut into semiconductor chips, or may be a package such as a chip size package (CSP).

A semiconductor section (semiconductor substrate, for example) 10 is provided. A part or the entirety of the semiconductor section 10 is formed of a semiconductor (silicon, for example). A plurality of elements 12 are formed in the semiconductor section 10. Each of the elements 12 makes up a transistor (MOS transistor, for example). As shown in FIG. 2, the elements 12 include a diffusion region (source or drain) 14 formed in the surface area of the semiconductor section 10, and an electrode (gate) 16 formed on the semiconductor section 10. A well of a different conductivity type may be formed in the surface area of the semiconductor section 10, and the diffusion region 14 may be formed in the well. The region of the elements 12 is called an active region. An element-isolation electrical insulating film (oxide film formed by a local-oxidation-of-silicon (LOCOS) method, for example) 18 is formed in the region (inactive region) of the semiconductor section 10 other than the elements 12.

An insulating layer 20 including one or more layers (first to third insulating layers 22, 24, and 26, for example) is formed on the semiconductor section 10. The insulating layer 20 may be formed of an oxide film (silicon oxide film, for example). An electrode pad 30 electrically connected with the element 12 is formed on the outermost surface of the insulating layer 20. An interconnect layer 40 including one or more layers (first and second interconnect layers 42 and 44, for example) may be formed between the semiconductor section 10 and the electrode pad 30. The interconnect layer 40 is electrically connected with the element 12. The interconnect layer 40 or the electrode pad 30 may be formed of a metal such as aluminum or copper.

In the example shown in FIG. 2, the first insulating layer 22 is formed on the semiconductor section 10, the first interconnect layer 42 is formed on the first insulating layer 22, and the element 12 (diffusion region 14, for example) and the first interconnect layer 42 are electrically connected through a contact section 50. The second insulating layer 24 is formed on the first interconnect layer 42, the second interconnect layer 44 is formed on the second insulating layer 24, and the first and second interconnect layers 42 and 44 are electrically connected through a contact section 52. The third insulating layer (uppermost insulating layer) 26 is formed on the second interconnect layer 42, the electrode pad 30 is formed on the third insulating layer 26, and the second interconnect layer 44 and the electrode pad 30 are electrically connected through a contact section 54. The interconnects can be routed while preventing an increase in the planar area by forming the interconnect layer to have a multilayer structure as described above.

The contact sections 50, 52, and 54 vertically pass through a part or the entirety of the insulating layer 20. The contact sections 50, 52, and 54 may be formed of a conductive material such as a metal. Some or all of the contact sections 50, 52, and 54 may be formed of a material the same as or different from the material for the interconnect layer 40 or the electrode pad 30.

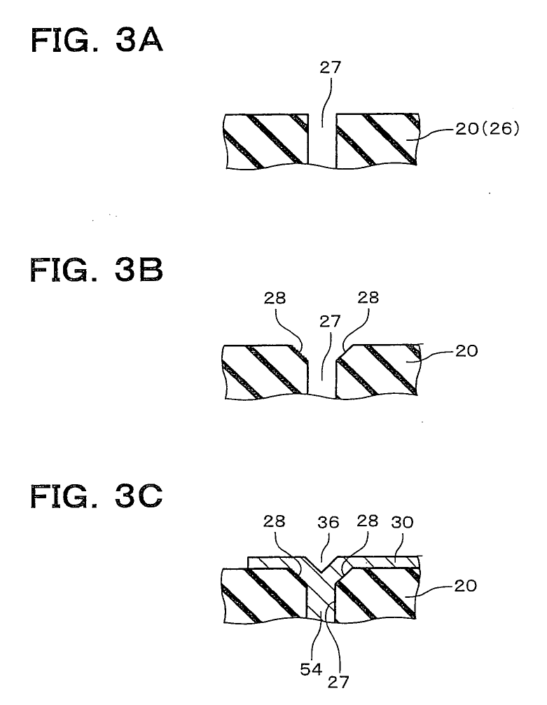

A formation method for the contact section (contact section connected with the electrode pad) and the electrode pad is described below with reference to FIGS. 3A to 3C.

As shown in FIG. 3A, the insulating layer 20 (third insulating layer 26 in this example) is formed by using a spin coating method, a chemical vapor deposition (CVD) method, or the like. A contact hole 27 is formed in the insulating layer 20 by photolithography and etching or the like. The contact hole 27 may be formed to have a wall surface, which is perpendicular to the surface of the insulating layer 20. As shown in FIG. 3B, a tapered surface (including flat surface or curved surface) 28 extending in the open direction may be formed at the open end of the contact hole 27. The tapered surface 28 may be formed by etching. The tapered surface 28 may be a surface continuously formed at the entire perimeter of the contact hole 27. The element 12 or the interconnect layer 40 (second interconnect layer 44, for example) is exposed from the contact hole 27. As shown in FIG. 3C, the electrode pad 30 and the contact section 54 are formed at the same time. The contact section 54 is formed in the contact hole 27, and the electrode pad 30 is formed on the surface of the insulating layer 20. The electrode pad 30 and the contact section 54 may be integrally deposited by sputtering. This enables the electrode pad 30 to be formed so that a depression 36 remains to follow the tapered surface 28 of the insulating layer 20 at a position at which the electrode pad 30 overlaps the contact section 54. The inner surface of the depression 36 is tapered to extend in the open direction.

The description of the contact section 54 and the electrode pad 30 may also be applied to the formation method for the contact sections 50 and 52 and the interconnect layer 40.

The interconnect layer may have a two-layer structure as described above, or may have a single-layer structure or a structure including three or more layers. Or, the interconnect layer may be omitted, and the element 12 (diffusion region 14) and the electrode pad 30 may be electrically connected directly through the (straight extending) contact section 54.

As shown in FIG. 2, a passivation film 60 is formed on the outermost surface of the insulating layer 20. The passivation film 60 is formed to have an opening 62 on a first section 32 (center section, for example) of the electrode pad 30 and to be positioned on a second section 34 (end section which continuously encloses the center section, for example). For example, a plurality of openings 62 may be formed in the passivation film 60 so that one of the openings 62 is disposed on the center section of each of the electrode pads 30. The first section 32 of the electrode pad 30 is exposed from the opening 62 in the passivation film 60. The second section 34 of the electrode pad 30 is covered with the passivation film 60. The passivation film 60 may be formed of an oxide film, a nitride film, a polyimide resin, or the like.

A barrier layer (under-bump metal layer) 64 is formed on the electrode pad 30. The barrier layer 64 may be formed to include one or more layers. The barrier layer 64 may be formed by sputtering. The barrier layer 64 prevents diffusion between the electrode pad 30 and the bump 70 described later. The barrier layer 64 may further have a function of increasing adhesion between the electrode pad 30 and the bump 70. The barrier layer 64 may include a titanium tungsten (TiW) layer. In the case where the barrier layer 64 includes a plurality of layers, the outermost surface of the barrier layer 64 may be an electroplating feed metal layer (Au layer, for example) for depositing the bump 70.

The barrier layer 64 covers the entire area of the electrode pad 30 exposed from the passivation film 60 (first section 32). A part of the barrier layer 64 may be formed above the second section 34 of the electrode pad 30 so that the barrier layer 64 is positioned on the passivation film 60. The barrier layer 64 is continuously formed from the first section 32 to the second section 34 of the electrode pad 30. As shown in FIG. 2, the barrier layer 64 may overlap a part or the entirety of the second section 34 of the electrode pad 30. The barrier layer 64 may overlap a region, which continuously encloses the opening 62 in the passivation film 60.

The bump 70 is formed on the electrode pad 30 (barrier layer 64 in more detail). The bump 70 may be formed by one or more layers of a metal such as gold, nickel, or copper. The bump 70 is formed to be larger than the opening 62 in the passivation film 60 and to be partially positioned on the passivation film 60. In other words, the bump 70 covers the entire opening 62 in the passivation film 60 and is also formed above the second section 34 of the electrode pad 30. The bump 70 is continuously formed from the first section 32 to the second section 34 of the electrode pad 30. As shown in FIG. 2, the bump 70 may overlap a part or the entirety of the second section 34 of the electrode pad 30. As shown in the partially enlarged view of FIG. 1, the bump 70 may overlap a region, which continuously encloses the opening 62 in the passivation film 60. The barrier layer 64 lies between the electrode pad 30 and the bump 70.

In this embodiment, the contact section 54 is connected with the second section 34 at a position within the range in which the contact section 54 overlaps the bump 70 while avoiding the first section 32 of the electrode pad 30. The contact section 54 lies between the interconnect layer 40 (second interconnect layer 44 in FIG. 2) and the electrode pad 30. The entire connection region between the contact section 54 and the electrode pad 30 is disposed in the second section 34 of the electrode pad 30. The depression 36 is formed on the second section 34 of the electrode pad 30 while avoiding the first section 32 of the electrode pad 30.

According to this configuration, as shown in FIG. 2, since the barrier layer 64 lies between the second section 34 of the electrode pad 30 and the bump 70 in addition to the passivation film 60, diffusion between the electrode pad 30 and the bump 70 can be more effectively prevented. Therefore, electrical connection reliability can be improved while using the process in which the planarization process is omitted and which causes the depression 36 to remain on the electrode pad 30.

The bump 70 (electrode pad 30) overlaps the formation region of the elements 12 in the semiconductor section 10. In more detail, a part or the entirety of the bump 70 overlaps a part or the entirety of the region (active region) of the element 12. The bumps 70 (electrode pads 30) may be arranged on the plane of the semiconductor section 10 in an area array (in a plurality of rows and columns). In this embodiment, since the contact section 54 is connected with the electrode pad 30 at a position within the range in which the contact section 54 overlaps the bump 70 and the interconnects are not uselessly routed (routed toward the outside, for example), the electrical characteristics can be improved.

As shown in FIG. 2, a plurality of the contact sections 54 connected with the electrode pad 30 may be provided. All the contact sections 54 are connected with the second section 34 at positions within the range in which the contact section 54 overlaps the bump 70 while avoiding the first section 32 of the electrode pad 30. As shown in FIG. 1, the contact sections 54 are arranged to enclose the opening 62 in the passivation film 60 (first section 32 of the electrode pad 30), for example.

The contact sections 54 may be symmetrically arranged around a center axis (axis which passes through the center of the bump and is included in the plane when viewed from the upper surface of the bump) 72 of the bump 70. In more detail, one of the contact sections 54 is symmetrically disposed with respect to another contact section 54 around the center axis 72 of the bump 70. The statement “symmetrically arranged around the center axis 72 of the bump 70” means that the contact sections 54 may be line-symmetrical around the center axis 72, or may be plane-symmetrical about a virtual plane including the center axis 72, or may be point-symmetrical around one point of the center axis 72. According to this configuration, since the contact sections 54 are symmetrically arranged, the mechanical stress applied through the bump 70 due to the packaging process or the like can be evenly dispersed. Therefore, occurrence of damage to the contact section 54 or the electrode pad 30 due to stress concentration can be prevented.

The contact sections 50 and 52, which are not connected with the electrode pad 30, may also be symmetrically arranged around the center axis 72 of the bump 70 in the same manner as the contact sections 54.

A semiconductor device according to this embodiment includes features, which may be derived from the above description.

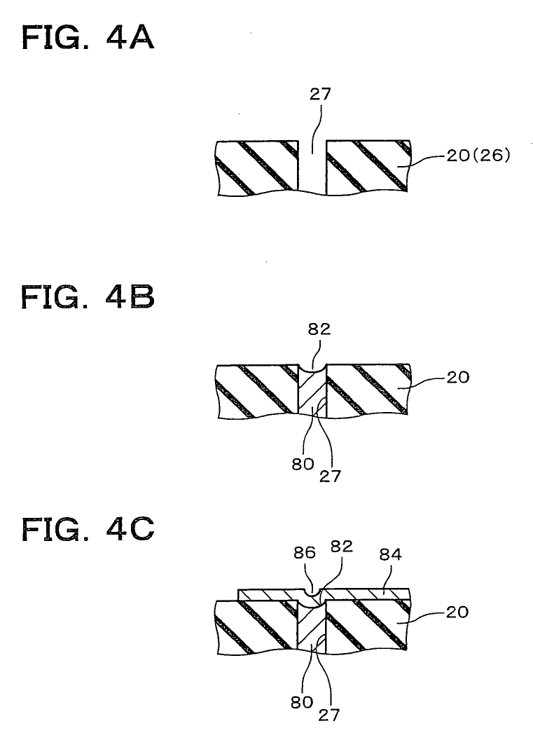

FIGS. 4A to 4C are diagrams illustrative of a modification of this embodiment. In this modification, the electrode pad 30 is formed after forming a contact section (contact section connected with the electrode pad).

As shown in FIG. 4A, the insulating layer 20 (third insulating layer 26 in this example) is formed, and the contact hole 27 is formed in the insulating layer 20. The element 12 or the interconnect layer 40 (second interconnect layer 44, for example) is exposed from the contact hole 27. The details of the insulating layer 20 and the contact hole 27 are the same as described above.

As shown in FIG. 4B, a contact section 80 is formed in the contact hole 27 in the insulating layer 20. For example, a material for the contact section may be deposited by applying a chemical vapor deposition (CVD) method. In this case, the contact section 80 is formed so that a depression 82 is formed in the contact hole 27. The depression 82 is a depression from the surface of the insulating layer 20.

As shown in FIG. 4C, an electrode pad 84 is formed on the surface of the insulating layer 20. The electrode pad 84 may be deposited by sputtering. This enables the electrode pad 84 to be formed so that a depression 86 remains to follow the depression 82 on the contact section 80 at a position at which the electrode pad 84 overlaps the contact section 80. The inner surface of the depression 86 may be formed by a curved surface. In this modification, electrical connection reliability can be improved while using a simplified process, which causes the depression 86, formed on the electrode pad 84 to remain. Other configurations and effects in this modification are the same as described above.

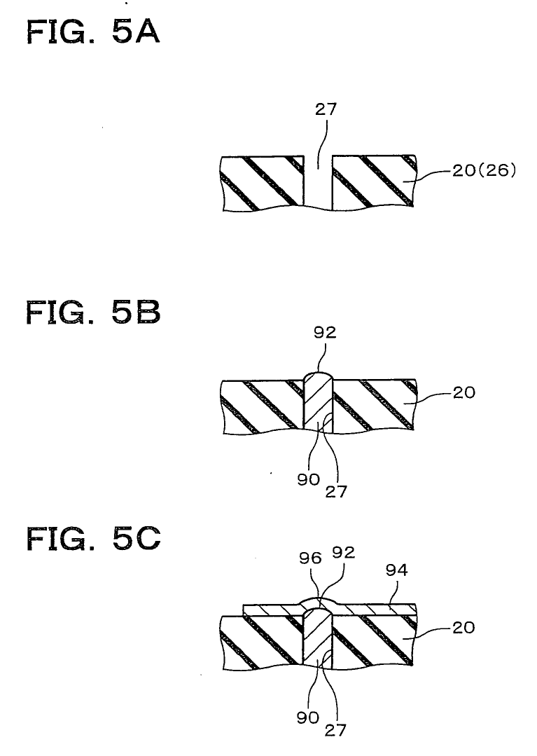

FIGS. 5A to 5C are diagrams illustrative of another modification of this embodiment. In this modification, the electrode pad 30 is formed after forming a contact section (contact section connected with the electrode pad) in the same manner as the above-described modification. However, this modification differs from the above-described modification in that a protrusion is formed on the electrode pad.

As shown in FIG. 5A, the insulating layer 20 (third insulating layer 26 in this example) is formed, and the contact hole 27 is formed in the insulating layer 20. The element 12 or the interconnect layer 40 (second interconnect layer 44, for example) is exposed from the contact hole 27. The details of the insulating layer 20 and the contact hole 27 are the same as described above.

As shown in FIG. 5B, a contact section 90 is formed in the contact hole 27 in the insulating layer 20. For example, a material for the contact section may be deposited by applying a chemical vapor deposition (CVD) method. In this case, the contact section 90 is formed so that a protrusion 92 is formed on the contact hole 27. The protrusion 92 protrudes from the surface of the insulating layer 20.

As shown in FIG. 5C, an electrode pad 94 is formed on the surface of the insulating layer 20. The electrode pad 94 may be deposited by sputtering. This enables the electrode pad 94 to be formed so that a protrusion 96 remains to follow the protrusion 92 on the contact section 90 at a position at which the electrode pad 94 overlaps the contact section 90. In this modification, electrical connection reliability can be improved while using a simplified process, which causes the protrusion 96, formed on the electrode pad 94 to remain. Other configurations and effects in this modification are the same as described above except that the depression on the electrode pad is replaced with the protrusion.

Although only some embodiments of the invention have been described in detail above, those skilled in the art will readily appreciate that many modifications are possible in the embodiments without materially departing from the novel teachings and advantages of this invention. Accordingly, all such modifications are intended to be included within scope of this invention. For example, the element type is not limited to a transistor, and includes a diffused resistor, diode, thyristor, capacitor, and the like. For example, the invention includes the case where an element is not be formed under the electrode pad and only an interconnect is formed.

What is claimed is:

1. A method of manufacturing a semiconductor device, the method comprising:
forming a first element;
forming a first insulating film above the first element, the first insulating film having a first hole for a first contact section;
forming an electrode pad on the first insulating film and the first contact section; and
forming a passivation film having an opening on the electrode pad, the opening not being positioned above the first contact section,
the electrode pad being to be electrically connected to a bump through the opening.

2. The method according to claim 1,
the electrode pad being electrically connected to a wire formed below the first insulating film through the first contact section.

3. The method according to claim 2, further comprising:
forming the bump electrically connected to the electrode pad.

4. The method according to claim 3, further comprising:
forming a barrier film on the electrode pad and above the passivation film.

5. The method according to claim 1,
the bump overlapping the first element in a plan view, the bump overlapping the first contact section in the plan view.

6. The method according to claim 1,
the first insulating film having a second hole for a second contact section; and
the first contact section and the second contact section being symmetrically arranged around a center axis of the bump.

7. The method according to claim 1,
the first element including a transistor including a gate, a source and a drain.

8. The method according to claim 1,
the first element being surrounded by a second insulating film.

9. The method according to claim 8,
the second insulating film insulating the first element from a second element adjacent to the first element.

10. The method according to claim 1,
the first contact section including at least one of aluminum and copper.

11. The method according to claim 1,
the electrode pad including at least one of aluminum and copper.

12. The method according to claim 4,
the barrier film including at least TiW.

13. The method according to claim 4,
the barrier film including TiW and Au.

14. The method according to claim 4,
a first position of a first edge of the barrier film being different from the second position of a second edge of the bump.

15. A method of manufacturing a semiconductor device, the method comprising:
forming a first active region of a semiconductor substrate;
forming a first insulating film above the first active region, the insulating film having a first hole for a first contact section;
forming an electrode pad on the insulating film and the first contact section; and
forming a passivation film having an opening on the electrode pad, the opening not being positioned above the first contact section,
the electrode pad being to be electrically connected to a bump through the opening.

16. The method according to claim 15,
the electrode pad being electrically connected to a wire formed below the first insulating film through the first contact section.

17. The method according to claim 16, further comprising:
forming the bump electrically connected to the electrode pad.

18. The method according to claim 17, further comprising:
forming a barrier film on the electrode pad and above the passivation film.

19. The method according to claim 15,
the bump overlapping the first active region in a plan view, the bump overlapping the first contact section in the plan view.

20. The method according to claim 15;
the first insulating film having a second hole for a second contact section; and
the first contact section and the second contact section being symmetrically arranged around a center axis of the bump.

21. The method according to claim 15,
the first active region including a source and a drain of a transistor.

22. The method according to claim 15,
the first active region being included in a transistor.

23. The method according to claim 14,
the first active region being surrounded by a second insulating film.

24. The method according to claim 23,
the second insulating film insulating the first active region from a second active region adjacent to the first active region.

25. The method according to claim 15,
the first contact section including at least one of aluminum and copper.

26. The method according to claim 15,
the electrode pad including at least one of aluminum and copper.

27. The method according to claim 15,
the barrier film including at least TiW.

28. The method according to claim 15,
the barrier film including TiW and Au.

29. The method according to claim 18,
a first position of a first edge of the barrier film being different from the second position of a second edge of the bump.

30. The method according to claim 29,
the first position being positioned inside the second position.
